(19) United States
(12) Patent Application Publication
(10) Pub. No.: US 2026/0238214 A1
(43) Pub. Date: Aug. 13, 2026

(54) CLOCK AND DATA RECOVERY CIRCUIT FOR REDUCING POWER CONSUMPTION AND CLOCK AND DATA RECOVERY METHOD THEREOF

(71) Applicant: NOVATEK Microelectronics Corp., Hsin Chu (TW)

(72) Inventors: Ho-Chun Chang, Hsinchu City (TW); Yu-Hsiang Wang, Hsinchu City (TW); Che-Wei Yeh, Hsinchu City (TW)

(73) Assignee: NOVATEK Microelectronics Corp., Hsin Chu (TW)

(21) Appl. No.: 19/051,217

(22) Filed: Feb. 12, 2025

(51) Int. Cl. H04L 7/033; H03L 7/08; H03L 7/085

(52) U.S. Cl. CPC H03L 7/0807; H03L 7/085; H04L 7/033

(57) ABSTRACT

A clock and data recovery circuit includes a phase detector and a data sorter. The phase detector includes N samplers and N comparators. The N samplers are used to sample a data signal using N clocks to generate N sampled values. N is an integer greater than 1. A comparator of the N comparators compares a phase of the data signal and a phase of a selected clock of the N clocks. The data sorter is coupled to the phase detector to determine a data order of the N sampled values and disable a subset of the N comparators according to the data order and a promised transition edge.

### BACKGROUND OF THE INVENTION

### 1. Field of the Invention

The present invention relates to communication systems, and specifically, to a clock and data recovery circuit for reducing power consumption and a clock and data recovery method thereof.

### 2. Description of the Prior Art

Clock and data recovery (CDR) is a critical process in digital data communication, where a separate clock signal is not transmitted alongside the data. CDR involves clock recovery and data recovery. In clock recovery, a recovered clock is generated by phase-aligning an internal clock to the transitions in an incoming data signal to synchronize the internal clock with the incoming data signal. In data recover, the incoming data signal is re-timed using the recovered clock to ensure accurate sampling. Accordingly, CDR enables accurate clock synchronization in the digital data communication system, ensuring reliable data transmission.

Traditional CDR circuits align the internal clock at every possible data transition to prevent the internal clock from being unlocked, resulting in significant power consumption.

### SUMMARY OF THE INVENTION

An embodiment provides a clock and data recovery circuit. The clock and data recovery circuit includes a phase detector and a data sorter. The phase detector includes N samplers and N comparators. The N samplers are used to sample a data signal using N clocks to generate sampled values. N is an integer greater than 1. A comparator of the N comparators compares a phase of the data signal and a phase of a selected clock of the N clocks. The data sorter is coupled to the phase detector to determine a data order of the sampled values and selectively disable the N comparators according to the data order and a promised transition edge.

Another embodiment provides a clock and data recovery method. The method includes sampling, by N samplers, a data signal using N clocks to generate sampled values, N being an integer greater than 1; comparing, by a comparator of N comparators, a phase of the data signal and a phase of a selected clock of the N clocks; determining, by a data sorter, a data order of sampled values; and selectively disabling, by the data sorter, the N comparators according to the data order and a promised transition edge.

These and other objectives of the present invention will no doubt become obvious to those of ordinary skill in the art after reading the following detailed description of the preferred embodiment that is illustrated in the various figures and drawings.

### BRIEF DESCRIPTION OF THE DRAWINGS

FIG. 1 is a clock and data recovery (CDR) circuit according to an embodiment of the present invention.

FIG. 2 is a flowchart of a clock and data recovery method of the CDR circuit in FIG. 1.

FIG. 3 is a circuit diagram of the phase detector in FIG. 1.

FIG. 4 is a schematic diagram of a bang-bang CDR method of the CDR circuit in FIG. 1.

FIG. 5 is a schematic diagram of a bang-bang CDR method of the CDR circuit in FIG. 1.

FIG. 6 is a clock and data recovery (CDR) circuit according to another embodiment of the present invention.

FIG. 7 is a circuit diagram of a CDR circuit in FIG. 6.

### DETAILED DESCRIPTION

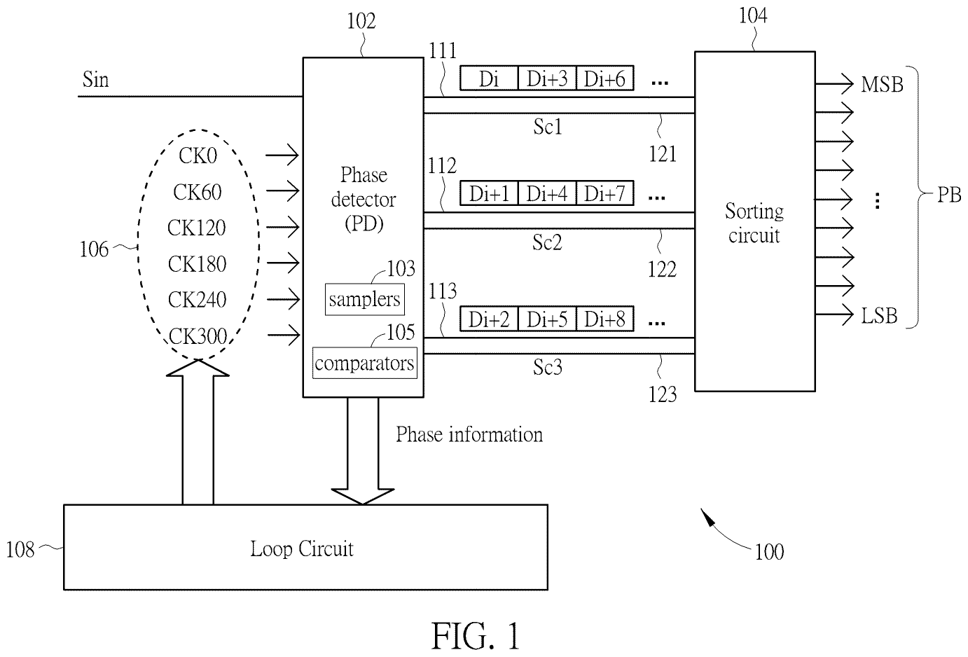

FIG. 1 is a clock and data recovery (CDR) circuit 100 for a ⅓ rate bang-bang system according to an embodiment of the present invention. The ⅓ rate refers to sampling data signal using three clocks with different phases. The CDR circuit 100 may sample a data signal Sin using clocks CK0, CK120, and CK240 to generate a sorted signal PB, where the three clocks CK0, CK120, and CK240 are 120 degrees apart in phase. The CDR circuit 100 may align phases of the clocks CK0, CK120, and CK240 to transitions in the data signal Sin to achieve clock recovery, and sample the data signal Sin using phase-aligned clocks CK0, CK120, and CK240 to achieve data recovery. The data signal Sin may be a video signal containing possible transitions and promised transitions. The possible transitions refer to points in the data signal Sin where a transition (from b′0 to b′1 or from b′1 to b′0) might occur, but is not guaranteed. The promised transitions refer to points in the data signal Sin where a transition is guaranteed to occur according to an encoding scheme or protocol. The CDR circuit 100 may disable (or turn off) circuit components associated with the possible transitions and enable (or turn on) circuit components associated with the promised transitions, achieving reliable clock phase alignment while reducing power consumption.

The data signal Sin may be transmitted in either differential or single-ended form from video sources such as a hard drive, a camera, a streaming service, or other sources. The sorted signal PB may contain sampled values of video data packets, each video data packet encapsulating a predetermined number of sampled values representing a specific pixel in a video frame. The sorted signal PB may be transmitted to a display device such as a liquid crystal display (LCD) for visual presentation.

The CDR circuit 100 may include a phase detector (PD) 102, a sorting circuit 104, N clocks 106, and a loop circuit 108. In the embodiment, N=6, the N clocks 106 includes clocks CK0, CK60, CK120, CK180, CK240, CK300, any two adjacent clocks being 60 degrees apart in phase, For the bang-bang architecture, the CDR circuit 100 may sample data transitions in the data signal Sin using clocks CK60, CK180, and CK300. The CDR circuit 100 may then compare the sampled values generated by the clocks CK0, CK120, and CK240 with the sampled values generated by the clocks CK60, CK180, and CK300 to determine lead/lag information of all the clocks 106. Subsequently, the loop circuit 108 may adjust phases of all the clocks 106 according to the respective lead/lag information. Specifically, the clocks CK0, CK60, CK120, CK180, CK240, CK300 may be phase-adjusted according to the lead/lag information, maintaining the phase difference of 60 degrees between adjacent clocks.

The phase detector 102 may include samplers 103 and comparators 105. The samplers may sample the values of data bits and the values of transitions between two consecutive data bits in the data signal Sin. The input of the phase detector 102 is the data signal Sin and the 6 clocks CK0, CK60, CK120, CK180, CK240, and CK300. The phase detector 102 may sample the data signal Sin using the clock CK0 to output sampled values Di, Di+3, and Di+6 on a data line 111, sample the data signal Sin using the clock CK120 to output sampled values Di+1, Di+4, and Di+7 on a data line 112, and sample the data signal Sin using the clock CK240 to output sampled values Di+2, Di+5, and Di+8 on a data line 113. The sorting circuit 104 may be coupled to the phase detector 102 via the 3 data lines 111, 112, 113 and 3 control lines 121, 122, 123. The phase detector 102 may transmit the sampled values to the sorting circuit 104 via the data lines 111, 112, 113, respectively. In addition, each one of the N comparators 105 may compare a phase of the data signal Sin and a phase of a corresponding clock of the N clocks 106 to generate the lead/lag information of the corresponding clock, and then pass the lead/lag information of the corresponding clock to the loop circuit 108.

The sorting circuit 104 may organize these sampled values from the data signal Sin into a specific sequence Di, Di+1, Di+2, Di+3, Di+4, Di+5, Di+6, Di+7, and Di+8 according to a known pattern. The known pattern may be a preamble sequence of a video frame, such as b′11110000. If the sampled values Di to Di+8 are b′011110000, the sorting circuit 104 may identify that the most significant bit (MSB) is the sampled value Di+1, while the least significant bit (LSB) is the sampled value Di+8, allowing the sorting circuit 104 to accurately interpret and segment all subsequent sampled values, ensuring that the video data is properly processed and decoded. The MSB and LSB may define a data order of the sampled values Di to Di+8. The sorting circuit 104 may selectively disable the N comparators and/or the N samplers according to the data order and a promised transition edge. In the embodiment, the sorting circuit 104 may transmit control signals Sc1, Sc2, and Sc3 to the phase detector 102 via the control lines 121, 122, 123, respectively, so as to selectively disable the N comparators and/or the N samplers. The loop circuit 108 may adjust the phases and frequencies of the clocks CK0, CK60, CK120, CK180, CK240, and CK300 according to the lead/lag information from the phase detector 102.

Upon power on, a clock training pattern may be transmitted in the data signal Sin to serve as a reference for the loop of the phase detector 102 to the sorting circuit 104 to synchronize and lock the clocks CK0, CK60, CK120, CK180, CK240, and CK300 onto the correct timing. Once the clocks CK0, CK60, CK120, CK180, CK240, and CK300 are successfully locked, the sorting circuit 104 may further perform power management on the CDR circuit 100 by utilizing the control signals Sc1, Sc2, and Sc3 transmitted via the control lines 121, 122, and 123 respectively, selectively enabling/disabling the samplers 103 and comparators 105 according to the data order and the promised transition edge. In the present invention, there is at least a promised transition edge in the video data packet. The promised transition edge refers to a specific point in the data signal where a change in state (from b′0 to b′1 or from b′1 to b′0) is expected to occur according to the encoding scheme or protocol being used. By selectively enabling the samplers 103 and comparators 105 associated with the promised transition edge, the CDR circuit 100 can accurately align the phases of the clocks CK0, CK60, CK120, CK180, CK240, and CK300 with the phase of the data signal Sin, thereby enhancing the reliability of clock and data recovery. Further, by selectively disabling samplers 103 and comparators 105 associated with the possible transitions (or not associated with the promised transition edge), the CDR circuit 100 can uses less power overall, being beneficial in low-power applications such as mobile devices or large-scale data centers.

The loop circuit 108 may include charge pumps, filters, and voltage control oscillators (VCOs) to control the phases and the frequencies of the clocks CK0, CK60, CK120, CK180, CK240, and CK300 according to the lead/lag information.

The promised transition edge may occur in a preamble sequence, a delimiter field of a data packet, or a redundant field of a data packet. Using the promised transition edge to generate the lead/lag information may enhance the reliability and reduce power consumption. In the present invention, the rate of the CDR circuit 100 is not limited to ⅓, and the number of data packet is not limited to 9. The number of the control lines and the number of the data lines are not limited to 3.

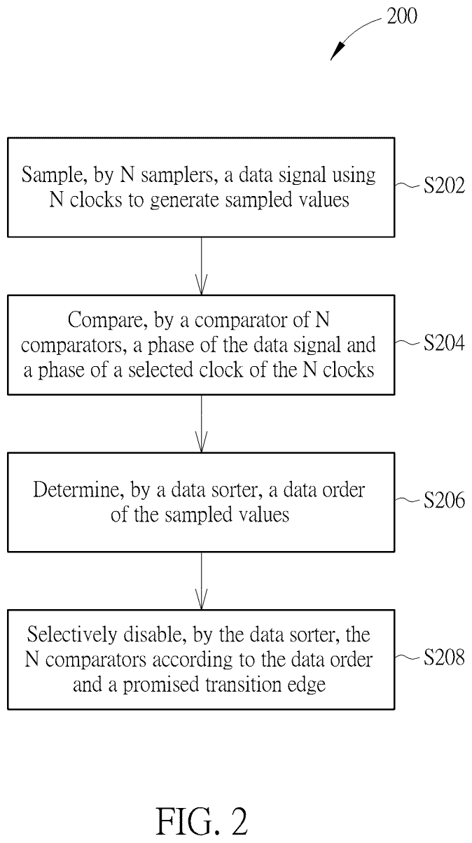

FIG. 2 is a flowchart of a method 200 of the CDR circuit 100. Any reasonable step change or adjustment is within the scope of the disclosure. The method 200 includes the following steps:
Step S202: Sample, by N samplers, a data signal using N clocks to generate sampled values;
Step S204: Compare, by a comparator of N comparators, a phase of the data signal and a phase of a selected clock of the N clocks;
Step S206: Determine, by a data sorter, a data order of sampled values; and
Step S208: Selectively disable, by the data sorter, the N comparators according to the data order and a promised transition edge.

The method 200 is now explained with reference to the CDR circuit 100. In Step S202, the data signal Sin is sampled by the N samplers 103 using the N clocks 106 to generate sampled values. In Step S204, a phase of the data signal and a phase of a selected clock of the N clocks 106 are compared by a comparator of the N comparator 105. In Step S206, a data order of the sampled values is determined by the sorting circuit 104. In Step S208, the N comparators 105 is selectively disabled by the sorting circuit 104 according to the data order and a promised transition edge.

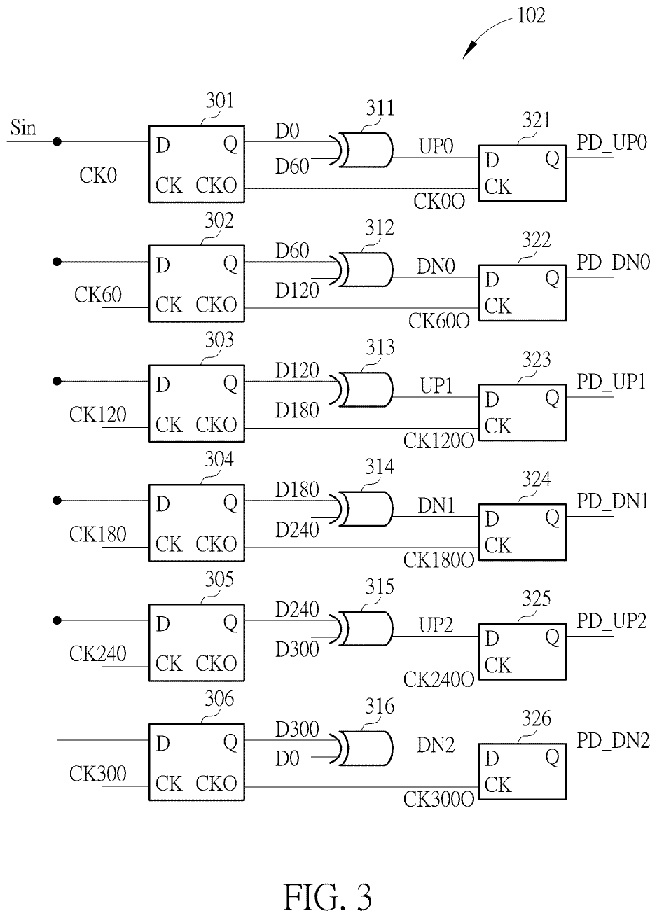

FIG. 3 is a circuit diagram of the phase detector 102. The phase detector 102 may include N samplers, N comparators, and N storage devices. In FIG. 3, N is 6, the phase detector 102 includes samplers 301 to 306, comparators 311 to 316, and storage devices 321 to 326. The samplers 301 to 306 may be implemented by flip-flops, the comparators 311 to 316 may be implemented by exclusive OR (XOR) gates, and the storage devices 321 to 326 may be implemented by flip-flops. The N samplers may include transition samplers and data samplers. The transition samplers and the data samplers may be equal or unequal in number. In some embodiments, the number of the transition samplers may be N/2, and the number of the data samplers may be N/2. In the embodiment, the number of transition samplers is 3, and the number of the data samplers is 3. The data samplers are used to sample data bits in the data signal Sin. The samplers 301, 303, and 305 may serve as the data samplers. The transition samplers are used to sample the values between two consecutive data bits in the data signal Sin, The samplers 302, 304, and 306 may serve as the transition samplers.

The sampler 301 may include a data port D configured to receive the data signal Sin, an input clock port CK configured to receive the clock CK0, an output port Q configured to generate a sampled value D0, and an output clock port CKO configured to output the clock CK0O. The clock CK0O may be identical to the clock CK0. The comparator 311 may include a first input port coupled to the output port Q of the sampler 301 to receive the sampled value D0, a second input port configured to receive a sampled value D60, and an output port configured to output a comparison result UP0. The storage device 321 may include a data port D coupled to the output port of the comparator 311 to receive the comparison result UP0, an input clock port CK coupled to the output clock port CKO of the sampler 301 to receive the clock CK0O, and an output port Q configured to generate phase information PD_UP0. The phase information PD_UP0 may be sent to the loop circuit 108 to determine the lead/lag information.

The sampler 302 may include a data port D configured to receive the data signal Sin, an input clock port CK configured to receive the clock CK60, an output port Q configured to generate a sampled value D60, and an output clock port CKO configured to output the clock CK60O. The clock CK60O may be identical to the clock CK60. The comparator 312 may include a first input port coupled to the output port Q of the sampler 302 to receive the sampled value D60, a second input port configured to receive a sampled value D120, and an output port configured to output a comparison result DN0. The storage device 322 may include a data port D coupled to the output port of the comparator 312 to receive the comparison result DN0, an input clock port CK coupled to the output clock port CKO of the sampler 302 to receive the clock CK60O, and an output port Q configured to generate phase information PD_DN0. The phase information PD_DN0 may be sent to the loop circuit 108 to determine the lead/lag information.

The sampler 303 may include a data port D configured to receive the data signal Sin, an input clock port CK configured to receive the clock CK120, an output port Q configured to generate a sampled value D120, and an output clock port CKO configured to output the clock CK120O. The clock CK120O may be identical to the clock CK120. The comparator 313 may include a first input port coupled to the output port Q of the sampler 303 to receive the sampled value D120, a second input port configured to receive a sampled value D180, and an output port configured to output a comparison result UP1. The storage device 323 may include a data port D coupled to the output port of the comparator 313 to receive the comparison result UP1, an input clock port CK coupled to the output clock port CKO of the sampler 303 to receive the clock CK120O, and an output port Q configured to generate phase information PD_UP1. The phase information PD_UP1 may be sent to the loop circuit 108 to determine the lead/lag information.

The sampler 304 may include a data port D configured to receive the data signal Sin, an input clock port CK configured to receive the clock CK180, an output port Q configured to generate a sampled value D180, and an output clock port CKO configured to output the clock CK180O. The clock CK180O may be identical to the clock CK180. The comparator 314 may include a first input port coupled to the output port Q of the sampler 304 to receive the sampled value D180, a second input port configured to receive a sampled value D240, and an output port configured to output a comparison result DN1. The storage device 324 may include a data port D coupled to the output port of the comparator 314 to receive the comparison result DN1, an input clock port CK coupled to the output clock port CKO of the sampler 304 to receive the clock CK180O, and an output port Q configured to generate phase information PD_DN1. The phase information PD_DN1 may be sent to the loop circuit 108 to determine the lead/lag information.

The sampler 305 may include a data port D configured to receive the data signal Sin, an input clock port CK configured to receive the clock CK240, an output port Q configured to generate a sampled value D240, and an output clock port CKO configured to output the clock CK240O. The clock CK240O may be identical to the clock CK240. The comparator 315 may include a first input port coupled to the output port Q of the sampler 305 to receive the sampled value D240, a second input port configured to receive a sampled value D300, and an output port configured to output a comparison result UP2. The storage device 305 may include a data port D coupled to the output port of the comparator 315 to receive the comparison result UP2, an input clock port CK coupled to the output clock port CKO of the sampler 305 to receive the clock CK240O, and an output port Q configured to generate phase information PD_UP2. The phase information PD_UP2 may be sent to the loop circuit 108 to determine the lead/lag information.

The sampler 306 may include a data port D configured to receive the data signal Sin, an input clock port CK configured to receive the clock CK300, an output port Q configured to generate a sampled value D300, and an output clock port CKO configured to output the clock CK300O. The clock CK300O may be identical to the clock CK300. The comparator 316 may include a first input port coupled to the output port Q of the sampler 306 to receive the sampled value D300, a second input port configured to receive a sampled value D0, and an output port configured to output a comparison result DN2. The storage device 326 may include a data port D coupled to the output port of the comparator 316 to receive the comparison result DN2, an input clock port CK coupled to the output clock port CKO of the sampler 306 to receive the clock CK300O, and an output port Q configured to generate phase information PD_DN2. The phase information PD_DN2 may be sent to the loop circuit 108 to determine the lead/lag information.

In one example, the sorting circuit 104 may determine that the MSB of a video data packet is generated by the clock CK0, and there is a promised transition edge to be sampled by the clock CK60. That is, the sampler 302 is the transition sampler of sampling the promised transition edge. The promised transition edge can occur in a preamble sequence (e.g., preamble sequence of a video frame), a delimiter field of a data packet (e.g., delimiter field of a video packet), or a redundant field of a data packet (e.g., error correction code (ECC)). The control of the phase detector 102 is now explained with reference to FIGS. 1 and 3. The control signal Sc1 may be used to enable/disable the sampler 302, the comparators 311, 312, and the storage devices 321, 322. The control signal Sc2 may be used to enable/disable the sampler 304, the comparators 313, 314, and the storage devices 323, 324. The control signal Sc3 may be used to enable/disable the sampler 306, the comparators 315, 316, and the storage devices 325, 326. In some embodiments, the sorting circuit 104 may selectively disable of the samplers 302, 304, 306, the comparators 311 to 316, and the storage devices 321 to 326 according to the data order and the promised transition edge. The disabled comparators may be independent of the transition sampler 302 of sampling the promised transition edge. That is, the disabled comparators 311 to 316 are comparators not coupled to the transition sampler 302. In the embodiment, the disabled comparators 311 to 316 may be the comparators 313 to 316.

When the promised transition edge is sampled by the clock CK60, the circuits in the phase detector 102 independent of the promised transition edge may be turned off. Therefore, the control signal Sc1 may be used to turn on the sampler 302, the comparators 311, 312, and the storage devices 321, 322. The control signal Sc2 may be used to turn off the sampler 304, the comparators 313, 314, and the storage devices 323, 324. The control signal Sc3 may be used to turn off the sampler 306, the comparators 315, 316, and the storage devices 325, 326. That is, the transition sampler 302 for sampling the promised transition edge is enabled, and the transition samplers 304 and 306 not for sampling the promised transition edge are disabled.

The samplers 301 samples the data signal Sin using the clock CK0 to generate a sampled value D0 representing data. The samplers 303 samples the data signal Sin using the clock CK120 to generate a sampled value D120 representing data. The samplers 305 samples the data signal Sin using the clock CK240 to generate a sampled value D240 representing data. The sampler 302 samples the data signal Sin using the clock CK60 to generate a sampled value D60 representing a promised transition edge. Since the sampled value D60 represents the promised transition edge, the sampled values D0 and D120 are opposite in state. For simplicity, the operations of the comparators 311 and 312 will be discussed in the scenario where the sampled value D0 is b′0 and the sampled value D120 is b′1.

The comparator 311 compares the sampled value D0 and sampled value D60 of the promised transition edge to generate the comparison result UP0. If the sampled value D60 is b′0, since the sampled value D0 is b′0, the comparison result UP0 will be b′0, indicating that the clock CK60 leads the promised transition edge. If the sampled value D60 is b′1, since the sampled value D0 is b′0, the comparison result UP0 will be b′1, indicating that the clock CK60 lags the promised transition edge. The compared result UP0 is then stored in the storage device 321. Subsequently, the storage device 321 outputs the phase information PD_UP0.

The comparator 312 compares the sampled value D60 of the promised transition edge and sampled value D120 to generate the comparison result DN0. If the sampled value D60 is b′0, since the sampled value D120 is b′1, the comparison result DN0 will be b′1, indicating that the clock CK60 leads the promised transition edge. If the sampled value D60 is b′1, since the sampled value D120 is b′1, the comparison result DN0 will be b′0, indicating that the clock CK0 lag the promised transition edge. The compared result DN0 is then stored in the storage device 322. Subsequently, the storage device 322 outputs the phase information PD_DN0.

The loop circuit 108 may determine the lead/lag information according to the phase information PD_UP0 and PD_DN0. If the phase information PD_UP0 is b′1 and the phase information PD_UD0 is b′0, the loop circuit 108 may determine that the clock CK60 lags the promised transition edge, and advance the phases of all the clocks 106. Conversely, if the phase information PD_UP0 is b′0 and the phase information PD_UD0 is b′1, the loop circuit 108 may determine that the clock CK60 leads the promised transition edge, and delay the phases of all the clocks 106. If the phase information PD_UP0 and PD_UD0 are both b′0, the loop circuit 108 may determine that there is no data transition in the data signal Sin, and keep the phases of all the clocks 106 unchanged.

For the promised transition, the phase information PD_UP0 and PD_DN0 are always the complements of each other. That is, when one of the phase information PD_UP0 and PD_DN0 is b′1, the other one is b′0. In some embodiments, the loop circuit 108 may determine the lag information according to the phase information PD_UP0 and determine the lag information according to the phase information PD_DN0. If the phase information PD_UP0 is b′1, the loop circuit 108 may determine that the clock CK60 lags the promised transition edge and advance the phases of all the clocks 106. If the phase information PD_DN0 is b′1, the loop circuit 108 may determine that the clock CK60 leads the promised transition edge and lag the phases of all the clocks 106.

When the promised transition edge is sampled by the clock CK 120 or CK 180, the comparators 313 and 314 or the comparator 315 and 316 may operate according to the similar principle as for the comparators 311 and 312, and the loop circuit 108 may determine the lead/lag information according to the phase information PD_UP1 and PD_DN1 or the phase information PD_UP2 and PD_DN2 using the similar principle as for the PD_UP0 and PD_DN0.

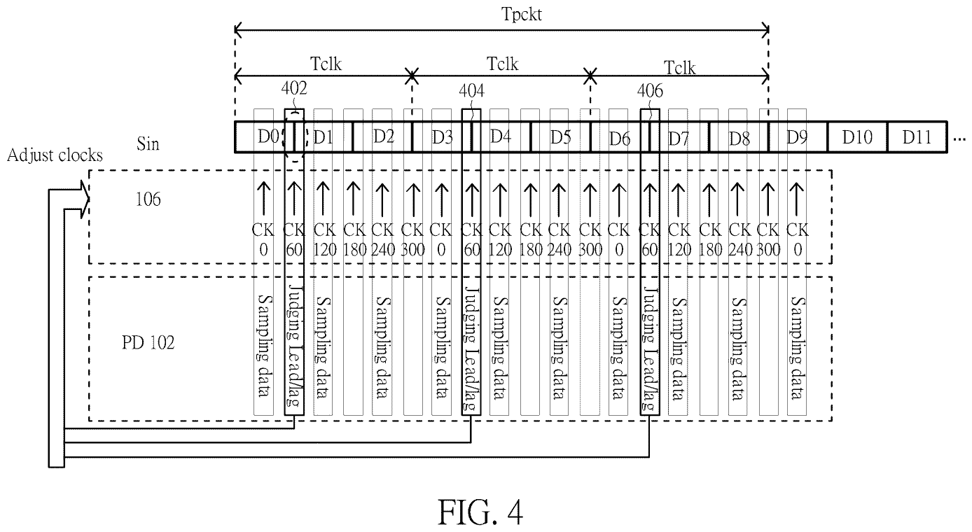

FIG. 4 is a schematic diagram of a bang-bang CDR method of the CDR circuit 100. FIG. 4 will be explained with reference to FIGS. 1 and 3. A data packet including 9 sampled values D0, D1, D2, D3, D4, D5, D6, D7, and D8 are sampled by the clocks CK0, CK120, and CK240 in a packet duration Tpckt. The packet duration Tpckt may include 3 clock cycle durations Tclk, During each clock cycle duration Tclk, the data signal Sin may be sampled exactly once by each of the clocks CK0, CK120, and CK240. The 9 bits data are generated by the samplers 301, 303, 305. The sampler 301 may generate the sampled values D0, D3, D6 using the clock CK0, the sampler 303 may generate the sampled value D1, D4, D7 using the clock CK120, and the sampler 305 may generate the sampled values D2, D5, D8 using the clock CK240. The sorting circuit 104 may enable the comparators 311 and 312 in a constant manner. If the protocol defines there is a promised transition (e.g., transitions 402 in FIG. 4) which always happens between D0 and D1 in every data packet, and the sorting circuit 104 succeeds to identify the correct packet order, then the sorting circuit 104 may enable the comparators 311 and 312 in a constant manner. That is, the comparators 311 and 312 remain in an “ON” state during the packet duration Tpckt. Further, the sorting circuit 104 may enable the samplers 301 to 303 and 305, and the storage devices 321 and 322 in the constant manner. The samplers 304 and 306, the comparators 313 to 316, and the storage devices 323 to 326 remain in an “OFF” state during the packet duration Tpckt.

During the first clock cycle duration Tclk, the sampled values D0 to D2 are generated sequentially, and a promised transition edge occurs between the sampled values D0 and D1. As a result, the sampled values D0 and D1 are opposite in state, specifically if the sampled value D0 is b′0 then the sampled value D1 is b′1, and vice versa. Accordingly, the sampler 302 samples the sampled value of the promised transition edge 402 using the clock CK60, the comparator 311 compares the sampled value of the promised transition edge 402 with the sampled values D0 to generate the phase information PD_UP0, and the comparator 312 compares the sampled value of the promised transition edge 402 with the sampled values D1 to generate the phase information PD_DN0. The loop circuit 108 may determine the lead/lag information according to the phase information PD_UP0 and PD_DN0, and the clocks 106 may be adjusted according to the lead/lag information.

The comparators 313 and 314 are turned off, generating no lead/lag information between the sampled values D1 and D2, leading to no phase adjustment of the clocks 106. Similarly, the comparators 315 and 316 are turned off, generating no lead/lag information between the sampled values D2 and D3, leading to no phase adjustment of the clocks 106.

During the second clock cycle duration Tclk, the sampled values D3 to D5 are generated sequentially, and a possible transition occurs between the sampled values D3 and D4. The sampler 302 samples the sampled value of the possible transition 404 using the clock CK60, the comparator 311 compares the sampled value of the possible transition 404 with the sampled values D3 to generate the phase information PD_UP0, and the comparator 312 compares the sampled value of the possible transition 404 with the sampled values D4 to generate the phase information PD_DN0. The loop circuit 108 may determine the lead/lag information according to the phase information PD_UP0 and PD_DN0. If a data transition occurs between the sampled values D3 and D4, the clocks 106 may be adjusted according to the lead/lag information.

The comparators 313 and 314 are turned off, generating no lead/lag information between the sampled values D4 and D5, leading to no phase adjustment of the clocks 106. Similarly, the comparators 315 and 316 are turned off, generating no lead/lag information between the sampled values D5 and D6, leading to no phase adjustment of the clocks 106.

During the third clock cycle duration Tclk, the sampled values D6 to D8 are generated sequentially, and a possible transition occurs between the sampled values D6 and D7. The sampler 302 samples the sampled value of the possible transition 406 using the clock CK60, the comparator 311 compares the sampled value of the possible transition 406 with the sampled values D6 to generate the phase information PD_UP0, and the comparator 312 compares the sampled value of the possible transition 406 with the sampled values D7 to generate the phase information PD_DN0. The loop circuit 108 may determine the lead/lag information according to the phase information PD_UP0 and PD_DN0. If a data transition occurs between the sampled values D6 and D7, the clocks 106 may be adjusted according to the lead/lag information.

The comparators 313 and 314 are turned off, generating no lead/lag information between the sampled values D7 and D8, leading to no phase adjustment of the clocks 106. Similarly, the comparators 315 and 316 are turned off, generating no lead/lag information between the sampled values D8 and D9, leading to no phase adjustment of the clocks 106.

In the present invention, the length of data packet is not limited to 9 but can be other positive integer, and the number of the promised transition edge is not limited to 1 but can be other positive integer.

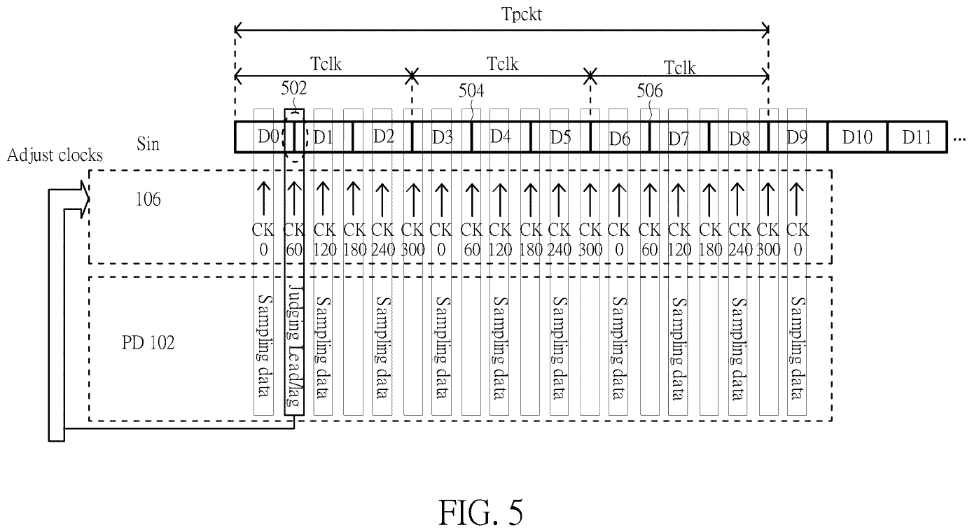

FIG. 5 is a schematic diagram of another bang-bang CDR method of the CDR circuit 100. The setting of FIG. 5 is similar to FIG. 4 except that the sorting circuit 104 may enable the comparators 311 and 312 in a cyclic manner. The protocol defines there is a promised transition (e.g., transitions 502 in FIG. 5) which always happens between D0 and D1 in every data packet, and the sorting circuit 104 succeeds to identify the correct packet order, then the sorting circuit 104 may enable the comparators 311 and 312 in the cyclic manner. That is, for each the packet duration Tpckt, the comparators 311 and 312 remain in the “ON” state during the first clock cycle duration Tclk and remain in the “OFF” state during the second and the third clock cycle duration Tclk. Further, the sorting circuit 104 may enable the samplers 301 to 303 and 305, and the storage devices 321 and 322 in the cyclic manner. The samplers 304 and 306, the comparators 313 to 316, and the storage devices 323 to 326 remain in the “OFF” state during the packet duration Tpckt.

In FIG. 5, the operations is similar to FIG. 4, with the exception that operations at the possible transition 504 between the sampled values D3 and D4 in the second clock cycle duration Tclk, and at the possible transition 506 between the sampled values D6 and D7 in the third clock cycle duration Tclk are different from those in FIG. 4. The following discussion will focus on the difference.

At the possible transition 504, the comparators 311 and 312 are turned off, generating no lead/lag information, leading to no phase adjustment of the clocks 106. Similarly, at the possible transition 506, the comparators 311 and 312 are turned off, generating no lead/lag information, leading to no phase adjustment of the clocks 106.

The sampler 302, the comparators 311 and 312, and the storage devices 321 and 322 are turned on and off periodically and only operate at the promised transition edge 502. Therefore, the operation time of the sampler 302, the comparators 311 and 312, and the storage devices 321 and 322 is shorter than that in FIG. 4, further enhancing reliability and reducing power consumption.

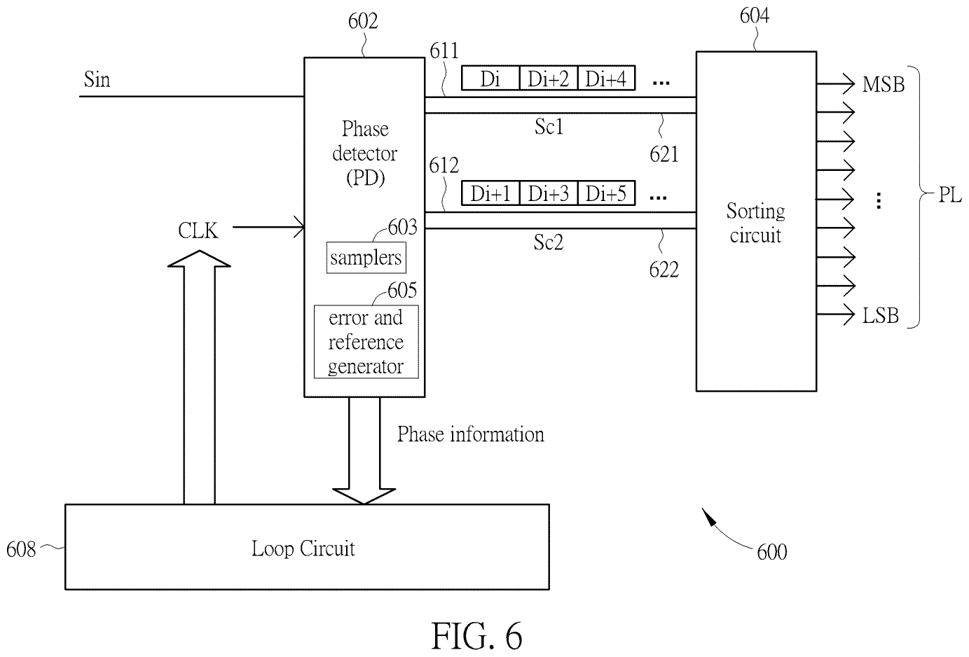

FIG. 6 is a clock and data recovery (CDR) circuit 600 for a ½ rate linear system according to an embodiment of the present invention. The ½ rate refers to sampling a data signal Sin using two clock phases. The linear CDR circuit 600 utilizes an analog phase detector to continuously extract phase information from the data signal Sin using a clock CLK, while the bang-bang CDR circuit 100 uses binary phase detectors to generate discrete lead or lag information. The CDR circuit 600 may sample the data signal Sin at two phases of the clock CLK to generate a sorted signal PL, the two phases of the clock CLK being 180 degrees out of phase with each other. In the embodiments, the rising edges and the falling edges may serve as the first clock phases and the second clock phases of the clock CLK, respectively. In some embodiments, the falling edges and the rising edges may serve as the first clock phases and the second clock phases of the clock CLK, respectively.

The CDR circuit 600 may include a phase detector (PD) 602, a sorting circuit 604, a clock CLK, and a loop circuit 608. The difference between the linear CDR circuit 600 and the bang-bang CDR circuit 100 lies in the configurations and operations of the phase detector 602, and will be discussed in detail in the subsequent paragraphs. The configurations and operations of other circuit components in the linear CDR circuit 600 are similar to those in the bang-bang CDR circuit 100 and will not be repeated here.

The phase detector 602 may receive the data signal Sin from a data source and the clock CLK from the loop circuit 608. The phase detector 602 may include samplers 603 and an error and reference generator 605. The samplers 603 may sample the data signal Sin using the rising edges of the clock CLK to output sampled values Di, Di+2, and Di+4 on a data line 611, and sample the data signal Sin using the falling edges of the clock CLK to output sampled values Di+1, Di+3, and Di+5 on a data line 612. The sorting circuit 604 (data sorter) is coupled to the phase detector 602 via the 2 data lines 611, 612. The sorting circuit 604 may sort the sampled values into a specific sequence of the sampled values Di, Di+1, Di+2, Di+3, Di+4, Di+5 according to the known pattern, and then transmit the ordered sequence as the sorted signal PL to a subsequent circuit for further processing.

The error and reference generator 605 may generate phase information according to the data signal Sin and the clock signal CLK. The phase information may include error pulses and reference pulses. The error pulses may represent the timing difference between a transition edge of the data signal Sin and a rising/falling edge of the clock signal CLK, The reference pulses may measure the interval between the consecutive rising and falling edges of the clock signal CLK. The error and reference generator 605 may send the phase information to the loop circuit 608.

The loop circuit 608 may include a charge pump, a filter, and a VCO to adjust the phases and the frequency of the clock CLK. The charge pump may receive the error pulses in an UP signal, and receive the reference pulses in a DOWN signal. When the error pulses appears in the UP signal, the charge pump raises the voltage of a charge pump signal; when the reference pulse appears in the DOWN signal, the charge pump lowers the voltage of the charge pump signal, regulating the level of the charge pump signal based on the UP and DOWN signals. The charge pump signal is passed through the filter to smooth out fluctuations and remove high-frequency noise, producing a stable VCO control voltage. The VCO adjusts the clock CLK's frequency based on the VCO control voltage, adapting the first and second clock phase to the phase detector 602. The CDR circuit 600 continuously adjusts the clock CLK's phases based on the phase information derived from the first and second clock phases.

The sorting circuit 604 may be further coupled to the phase detector 602 via 2 control lines 621, 622, and may disable circuit components in the error and reference generator 605 according to the data order and a promised transition edge using the control signals Sc1 and Sc2 transmitted via the control lines 621 and 622, respectively.

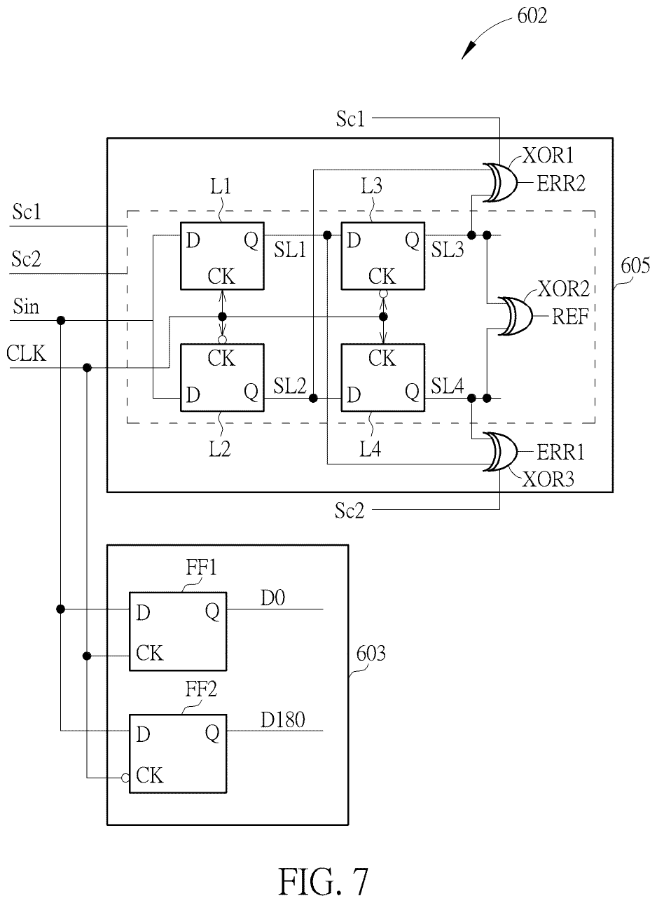

FIG. 7 is a circuit diagram of the phase detector 602. The samplers 603 may include flip-flops FF1 and FF2. The error and reference generator 605 may include latches L1 to L4 and exclusive-OR gates XOR1 to XOR3. The samplers 603 and the error and reference generator 605 may receive the data signal Sin and the clock signal CLK. The error and reference generator 605 may further receive the control signals Sc1 and Sc2.

The flip-flop FF1 includes an input terminal D to receive the data signal Sin; a clock terminal CK to receive the rising edge of the clock signal CLK; and an output terminal Q to generate a sampled data signal D0. The flip-flop FF2 includes an input terminal D to receive the data signal Sin; a clock terminal CK to receive the falling edge of the clock signal CLK; and an output terminal Q to generate a sampled data signal D180.

The latch L1 includes an input terminal D to receive the data signal Sin; a clock terminal CK to receive the rising edge of the clock signal CLK; and an output terminal Q to generate a latch signal SL1. The latch L2 includes an input terminal D to receive the data signal Sin; a clock terminal CK to receive the falling edge of the clock signal CLK; and an output terminal Q to generate a latch signal SL2. The latch L3 includes an input terminal D coupled to the output terminal Q of the latch L1; a clock terminal CK to receive the falling edge of the clock signal CLK; and an output terminal Q to generate a latch signal SL3. The latch L4 includes an input terminal D coupled to the output terminal Q of the latch L2; a clock terminal CK to receive the rising edge of the clock signal CLK; and an output terminal Q to generate a latch signal SL4. The XOR gate XOR1 includes a first input terminal coupled to the output terminal Q of the latch L2 to receive the latch signal SL2; a second input terminal coupled to the output terminal Q of the latch L3 to receive the latch signal SL3; and an output terminal to output error pulses on an error signal ERR2. The XOR gate XOR2 includes a first input terminal coupled to the output terminal Q of the latch L3 to receive the latch signal SL3; a second input terminal coupled to the output terminal Q of the latch L4 to receive the latch signal SL4; and an output terminal to output reference pulses on a reference signal REF. The XOR gate XOR3 includes a first input terminal coupled to the output terminal Q of the latch L4 to receive the latch signal SL4; a second input terminal coupled to the output terminal Q of the latch L1 to receive the latch signal SL1; and an output terminal to output error pulses on an error signal ERR1. Accordingly, the error signals ERR1 and ERR2 may serve as the UP signal to the charge pump, and the reference signal REF may serve as the DOWN signal to the charge pump.

The XOR gate XOR1 may be disabled by the control signals Sc1, while the XOR gate XOR3 may be disabled by the control signals Sc2. The latches L1 to L4 and the XOR gate XOR2 may be disabled by the control signals Sc1 and Sc2.

In various embodiments of the invention, the CDR circuits and CDR methods are implemented to disable circuit components according to data order and a promised transition edge, enhancing the reliability while saving power.

Those skilled in the art will readily observe that numerous modifications and alterations of the device and method may be made while retaining the teachings of the invention. Accordingly, the above disclosure should be construed as limited only by the metes and bounds of the appended claims.

What is claimed is:

1. A clock and data recovery circuit comprising:
a phase detector comprising:
N samplers to sample a data signal using N clocks to generate sampled values, N being an integer greater than 1; and
N comparators, a comparator of the N comparators comparing a phase of the data signal and a phase of a selected clock of the N clocks; and
a data sorter coupled to the phase detector to determine a data order of the sampled values, and selectively disable the N comparators according to the data order and a promised transition edge.

2. The circuit of claim 1, further comprising control lines coupled to the data sorter and the phase detector to transmit the control signals from the data sorter to the phase detector to selective disable the N comparators.

3. The circuit of claim 1, wherein the data sorter further enables remaining comparators of the N comparators in a cyclic manner.

4. The circuit of claim 1, wherein the data sorter further enables remaining comparators of the N comparators in a constant manner.

5. The circuit of claim 1, wherein the promised transition edge occurs in a preamble sequence.

6. The circuit of claim 1, wherein the promised transition edge occurs in a delimiter field of a data packet.

7. The circuit of claim 1, wherein the promised transition edge occurs in a redundant field of a data packet.

8. The circuit of claim 1, wherein the data sorter further selectively disables the N samplers according to the data order and the promised transition edge.

9. The circuit of claim 8, wherein:
the N samplers comprises transition samplers of sampling transition edges; and
the data sorter identifies a target transition sampler of sampling the promised transition edge from the transition samplers according to the data order, and disables a remaining transition sampler of the transition samplers.

10. The circuit of claim 9, wherein:
the comparator is coupled to 2 corresponding samplers of the N samplers to compare 2 respective sampled values to generate a comparison result; and
the data sorter disables any comparator from the N comparators that is not coupled to the target transition sampler.

11. The circuit of claim 10, wherein the phase detector further comprises:
N storage devices, each storage device being coupled to a corresponding comparator of the N comparators to store a comparison result from the corresponding comparator; and
the data sorter further selectively disables the N storage devices according to the data order and the promised transition edge.

12. The circuit of claim 11, wherein the data sorter disables any storage device from the N storage devices that is not coupled to the target transition sampler.

13. A clock and data recovery method comprising:
sampling, by N samplers, a data signal using N clocks to generate sampled values, N being an integer greater than 1;
comparing, by a comparator of N comparators, a phase of the data signal and a phase of a selected clock of the N clocks;
determining, by a data sorter, a data order of sampled values; and
selectively disabling, by the data sorter, the N comparators according to the data order and a promised transition edge.

14. The method of claim 13, wherein disabling, by the data sorter, the subset of the N comparators according to the data order and the promised transition edge comprises:
transmitting, from the data sorter via control lines to the phase detector, control signals to selectively disable the N comparators.

15. The method of claim 13, further comprises the data sorter enabling remaining comparators of the N comparators in a cyclic manner.

16. The method of claim 13, further comprises the data sorter enabling remaining comparators of the N comparators in a constant manner.

17. The method of claim 13, wherein the promised transition edge occurs in a preamble sequence.

18. The method of claim 13, wherein the promised transition edge occurs in a delimiter field of a data packet.

19. The method of claim 13, wherein the promised transition edge occurs in a redundant field of a data packet.

20. The method of claim 13, further comprising:
selectively disabling, by the data sorter, the N samplers according to the data order and the promised transition edge.

21. The method of claim 20, wherein the N samplers comprises transition samplers of sampling transition edges; and
selectively disabling, by the data sorter, the N samplers according to the data order and the promised transition edge comprises:
identifying, by the data sorter, a target transition sampler of sampling the promised transition edge from the transition samplers according to the data order; and
disabling, by the data sorter, a remaining transition sampler of the transition samplers.

22. The method of claim 21, wherein the comparator is coupled to 2 corresponding samplers of the N samplers to compare 2 respective sampled values to generate a comparison result; and
selectively disabling, by the data sorter, the N comparators according to the data order and the promised transition edge comprises:
disabling, by the data sorter, any comparator from the N comparators that is not coupled to the target transition sampler.

23. The method of claim 22, further comprising:
storing, by a storage device of N storage devices, a comparison result from a corresponding comparator; and
selectively disabling, by the data sorter, the N storage devices according to the data order and the promised transition edge.

24. The method of claim 23, wherein selectively disabling, by the data sorter, the N storage devices according to the data order and the promised transition edge comprises:
disabling, by the data sorter, any storage device from the N storage devices that is not coupled to the target transition sampler.
